(19) United States
(12) Patent Application Publication
(10) Pub. No.: US 2017/0367206 A1
(43) Pub. Date: Dec. 21, 2017

(54) ELECTRONIC DEVICE

(71) Applicant: Delta Electronics, Inc., Taoyuan City (TW)

(72) Inventors: Ming-Tang YANG, Taoyuan City (TW); Chun-Hsiung YEH, Taoyuan City (TW); Shih-Lin LAI, Taoyuan City (TW)

(21) Appl. No.: 15/466,288

(22) Filed: Mar. 22, 2017

(30) Foreign Application Priority Data
Jun. 20, 2016 (TW) 105119269

(51) Int. Cl. H05K 7/14; H01R 12/72; H05K 1/14

(52) U.S. Cl. CPC H05K 7/1407; H05K 1/144; H01R 12/721; H05K 2201/09063

(57) ABSTRACT

An electronic device is provided, including a first circuit board, a second circuit board, a supporting member, and a first locking member. The first circuit board has a first hole. The second circuit board has a second hole, a pin, and a metal connector, wherein the pin is connected to the first circuit board. The supporting member has a first portion disposed in the first hole, a second portion, and a screw hole extending from the first portion to the second portion, wherein the diameter of the first portion is less than that of the second portion. The first locking member passes through the second hole and enters the screw hole to affix the second circuit board to the supporting member. The second portion is disposed between the first circuit board and the second circuit board to form a gap therebetween.

### CROSS REFERENCE TO RELATED APPLICATIONS

The present application is based on, and claims priority from, Patent Application No. 105119269, filed on Jun. 20, 2016, the disclosure of which is hereby incorporated by reference herein in its entirety.

### BACKGROUND OF THE INVENTION

### Field of the Invention

The application relates in general to an electronic device, and in particular, to an electronic device having a supporting member.

### Description of the Related Art

In a conventional electronic device, there are a number of metal connectors disposed in a position that is higher than the mainboard for the purpose of connecting to an external device. Thus, a heat-resistant plastic sheet is usually disposed between the mainboard and a circuit board having metal connecters. The mainboard, the plastic sheet, and the circuit board can be affixed together with a rivet, and the mainboard can further be affixed to a housing with a screw.

However, the plastic sheet, the rivet, and the screw occupy a large amount of space, and these members for affixing and raising the position are not cheap. The user has to simultaneously align the holes on the mainboard, the plastic sheet, and the circuit board having metal connectors during assembly, in order to allow the rivet to pass through. Furthermore, the distances between the metal connectors and the mainboard, the metal connectors and the housing, and the mainboard and the housing have to be adjusted simultaneously. Therefore, the assembly method should be accurate and complex, and the cost of automated manufacturing is increased.

### BRIEF SUMMARY OF INVENTION

To address the deficiencies of conventional products, an embodiment of the invention provides an electronic device, including a first circuit board, a second circuit board, a supporting member, and a first locking member. The first circuit board has a first hole. The second circuit board has a second hole, a pin, and a metal connector, wherein the pin is connected to the first circuit board. The supporting member has a first portion disposed in the first hole, a second portion, and a screw hole extending from the first portion to the second portion, wherein the diameter of the first portion is less than that of the second portion. The first locking member passes through the second hole and enters the screw hole to affix the second circuit board to the supporting member. The second portion is disposed between the first circuit board and the second circuit board to form a gap therebetween.

In some embodiments, the diameter of the first portion is substantially the same as that of the first hole.

In some embodiments, the second portion contacts the first circuit board.

In some embodiments, the supporting member further comprises a third portion disposed in the second hole, wherein the diameter of the third portion is less than that of the second portion. The screw hole extends to the third portion.

In some embodiments, the diameter of the third portion is substantially the same as that of the second hole.

In some embodiments, the electronic device further comprises a housing and a second locking member. The housing has a third hole, and the second locking member passes through the third hole and enters the screw hole to affix the first circuit board to the housing.

In some embodiments, the first locking member and the second locking member are disposed on opposite sides of the first circuit board.

In some embodiments, the first circuit board further comprises a first surface and a second surface opposite to the first surface, wherein the second portion is disposed on the second surface, and the first portion protrudes from the first surface.

In some embodiments, the supporting member is affixed to the first circuit board by welding or pressing.

In some embodiments, the first circuit board is substantially parallel to the second circuit board.

Another embodiment of the invention provides an electronic device, including a first circuit board, a second circuit board, a supporting member, and a first locking member. The first circuit board has a first hole, wherein the first hole has a plane portion. The second circuit board has a second hole, a pin, and a metal connector, wherein the pin is connected to the first circuit board. The supporting member has a first portion disposed in the first hole, a second portion, and a screw hole extending from the first portion to the second portion, wherein the width of the first portion is less than the diameter of the second portion, and the width and the shape of the first portion are substantially the same as that of the first hole. The first locking member passes through the second hole and enters the screw hole to affix the second circuit board to the supporting member. The second portion is disposed between the first circuit board and the second circuit board to form a gap therebetween.

In some embodiments, the first hole has an opening.

In some embodiments, the second portion contacts the first circuit board.

In some embodiments, the supporting member further comprises a third portion disposed in the second hole, wherein the diameter of the third portion is less than that of the second portion. The screw hole extends to the third hole.

In some embodiments, the diameter of the third portion is substantially the same as that of the second hole.

In some embodiments, the supporting member further comprises a fourth portion connected to the first portion, and the first portion is positioned between the second portion and the fourth portion, wherein the width of the first portion is less than the diameter of the fourth portion.

In some embodiments, the height of first portion is substantially the same as that of the first hole.

In some embodiments, the electronic device further comprises a housing and a second locking member. The housing has a third hole, and the second locking member passes through the third hole and enters the screw hole to affix the first circuit board to the housing.

In some embodiments, the first locking member and the second locking member are disposed on opposite sides of the first circuit board.

In some embodiments, the first circuit board is substantially parallel to the second circuit board.

### BRIEF DESCRIPTION OF DRAWINGS

The invention can be more fully understood by reading the subsequent detailed description and examples with references made to the accompanying drawings, wherein:

FIG. 1A is a schematic diagram of an electronic device according to an embodiment of the invention;

FIG. 1B is an exploded diagram of an electronic device according to an embodiment of the invention;

FIG. 2 is a schematic diagram of an supporting member according to an embodiment of the invention;

FIG. 3 is a cross-sectional view along line x-x in FIG. 1A;

FIG. 4 is a left side view of an electronic device according to an embodiment of the invention;

FIG. 5A is a schematic diagram of an electronic device according to another embodiment of the invention;

FIG. 5B is a schematic diagram of an electronic device according to another embodiment of the invention;

FIG. 6A is a schematic diagram of an electronic device according to another embodiment of the invention;

FIG. 6B is an exploded diagram of an electronic device according to another embodiment of the invention;

FIG. 7 is a schematic diagram of an supporting member according to another embodiment of the invention;

FIG. 8 is a top view of a first circuit board according to another embodiment of the invention; and

FIG. 9 is a cross-sectional view along line y-y in FIG. 6A.

### DETAILED DESCRIPTION OF INVENTION

The embodiments of the electronic device are discussed in detail below. It should be appreciated, however, that the embodiments provide many applicable inventive concepts that can be embodied in a wide variety of specific contexts. The specific embodiments discussed are merely illustrative of specific ways to make and use the embodiments, and do not limit the scope of the disclosure.

Unless defined otherwise, all technical and scientific terms used herein have the same meaning as commonly understood to one of ordinary skill in the art to which this invention belongs. It should be appreciated that each term, which is defined in a commonly used dictionary, should be interpreted as having a meaning conforming to the relative skills and the background or the context of the present disclosure, and should not be interpreted by an idealized or overly formal manner unless defined otherwise.

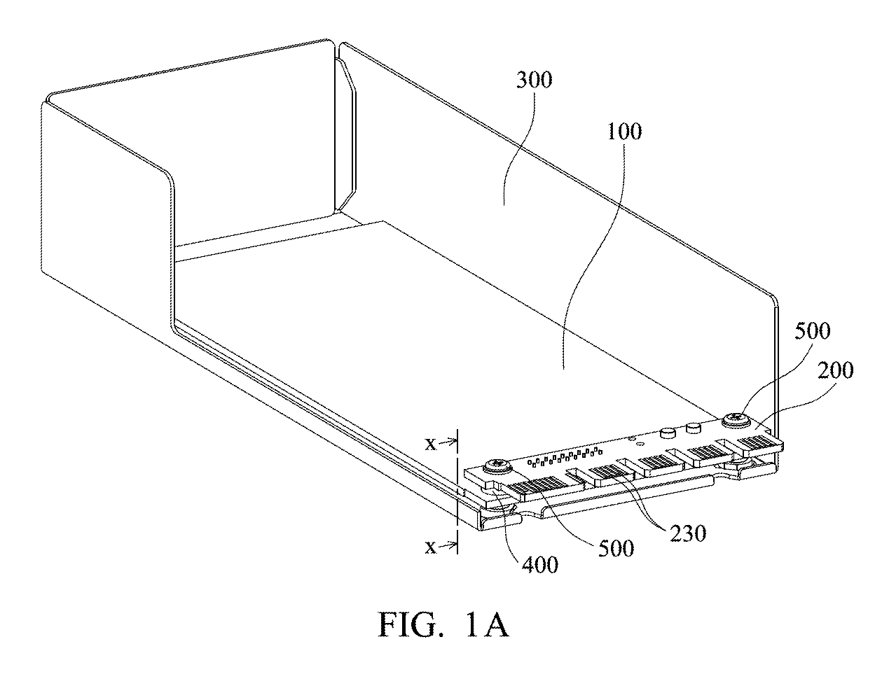

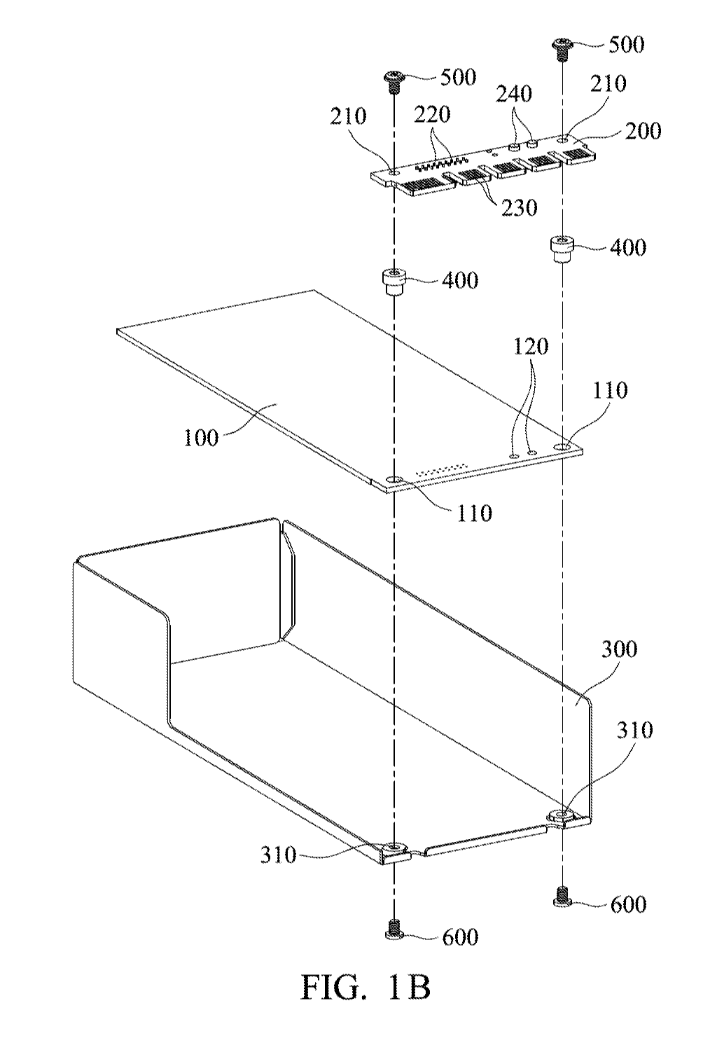

As shown in FIGS. 1A and 1B, an electronic device in an embodiment of the invention primarily comprises a first circuit board 100, a second circuit board 200, a housing 300, at least one supporting member 400, at least one first locking member 500, and at least one second locking member 600. At least one first hole 110 and a plurality of perforations 120 are formed on the first circuit board 100. At least one second hole 210, at least one pin 220, at least one metal connector 230, and a plurality of copper pillars 240 are formed on the second circuit board 200. Furthermore, at least one third hole 310 is formed on the housing 300.

It should be noted that the first hole 110, the second hole 210, and the third hole 310 are aligned with each other, and the copper pillars 240 are aligned with the perforations 120. In other words, the relative position between the first hole 110 and the perforations 120 is the same as the relative position between the second hole 210 and the copper pillars 240.

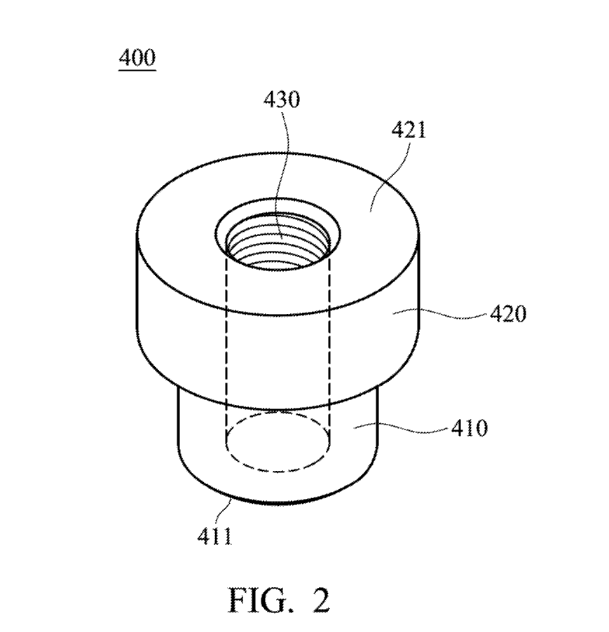

Referring to FIG. 2, the supporting member 400 has a stepped structure and comprises a first portion 410, a second portion 420, and a screw hole 430, wherein the screw hole 430 extends from the bottom 411 of the first portion 410 to the top 421 of the second portion 420. The dimensions or the diameter of the first portion 410 is less than that of the second portion 420.

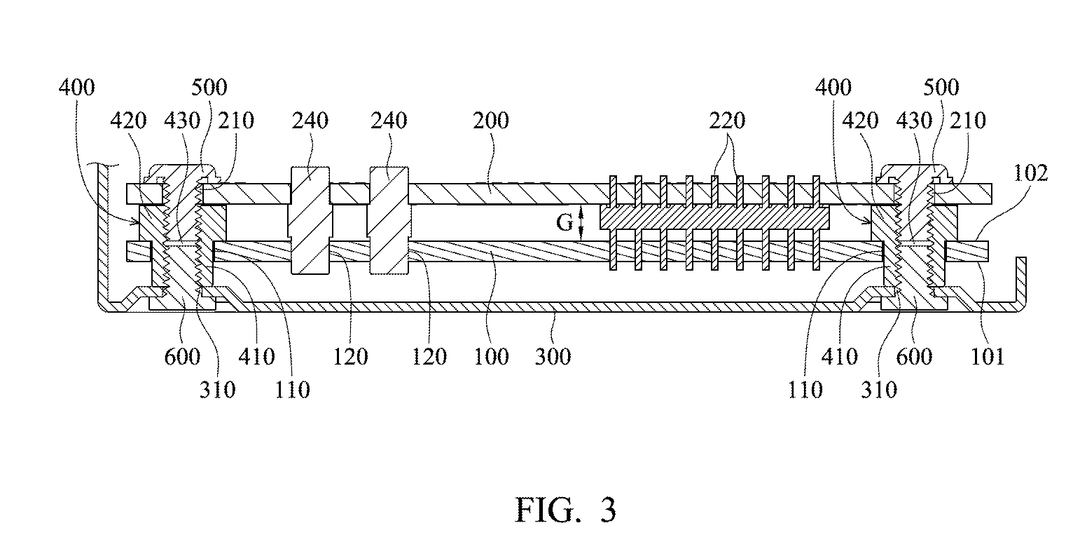

As shown in FIG. 3, when the aforementioned members are assembled, the supporting member 400 is affixed to the first circuit board 100. The first portion 410 of the supporting member 400 is disposed in the first hole 110 and protrudes from a first surface 101 of the first circuit board 100, and the second portion 420 contacts a second surface 102, wherein the second surface 102 is opposite to the first surface 101. The first locking member 500 passes through the second hole 210 of the second circuit board 200 and enters the screw hole 430 from the second portion 420 to join to the supporting member 400, such that the second circuit board 200 can be affixed to the supporting member 400. Because the second portion 420 of the supporting member 400 is disposed between the first circuit board 100 and the second circuit board 200, a gap G can be formed between the first circuit board 100 and the second circuit board 200. Therefore, the position of the second circuit board 200 can be raised.

The second locking member 600 passes through a third hole 310 of the housing 300 and enters the screw hole 430 from the first portion 410 to join to the supporting member 400, such that the first circuit board 100 can be affixed to the housing 300. Similarly, the part of the first portion 410 that protrudes from the first circuit board 100 can separate the first circuit board 100 from the housing 300. Thus, the first circuit board 100 does not contact the housing 300 to generate a short circuit even if the housing 300 comprises a conductive material (such as a metal).

The first and second locking members 500 and 600 respectively enter the screw hole 430 from the opposite ends of the supporting member 400, such that the first locking member 500 and the second locking member 600 are disposed on opposite sides of the first circuit board 100. In this embodiment, the first and second locking members 500 and 600 can be screws. The supporting member 400 can comprise non-conductive material, such as plastic or ceramics.

Referring to FIG. 3, when the electronic device is assembled, the pins 220 of the second circuit board 200 connect the first circuit board 100, and the copper pillars 240 pass through the perforations 120 to connect the first circuit board 100. The first and second circuit boards 100 and 200 can transmit signals and power therebetween by the pins 220 and the copper pillars 240.

In this embodiment, the pins 220 and the copper pillars 240 can be affixed to the first circuit board 100 by welding, and the supporting members 400 can be affixed to the first circuit board 100 by welding or pressing. Thus, the pins 220, the copper pillars 240, and the supporting members 400 can be affixed in the same step of the process. The automated manufacturing of the product can be facilitated. For example, the pins 200, the copper pillars 240, and the supporting members 400 can be welded by a surface-mount technology (SMT) to affix it to the first circuit board 100 in the same step of the process.

Furthermore, the diameter of the first portion 410 of the supporting member 400 is substantially the same as that of the first hole 110. Therefore, the first portion 410 does not move relative to the first hole 110 when the electronic device sways, and the separation of the supporting member 400 from the first circuit board 100 can be avoided.

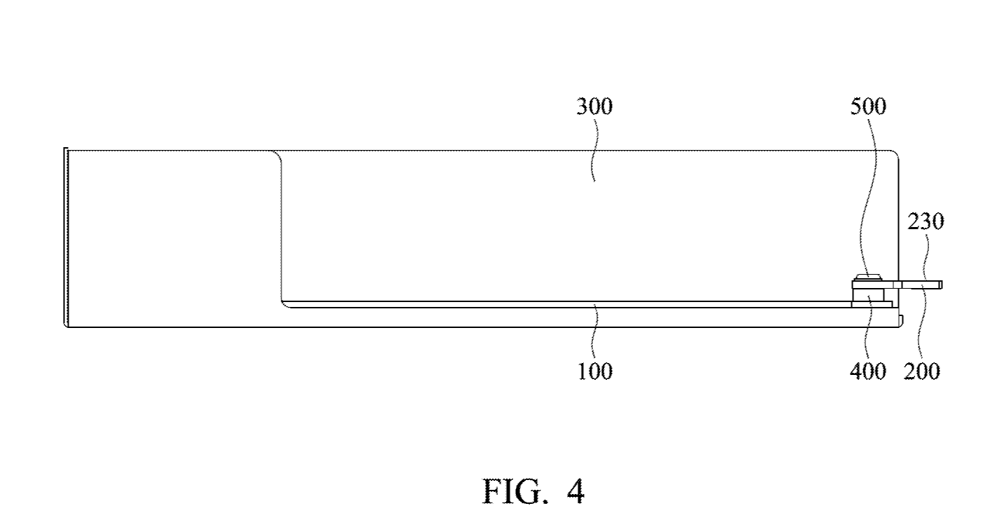

Referring to FIG. 4, in this embodiment, the first circuit board 100 is parallel to the second circuit board 200, and the metal connectors 230 of the second circuit board 200 protrude from the side of the first circuit board 100. An external device (for example, a USB flash drive or a connector of a display) can easily connect to the metal connectors 230.

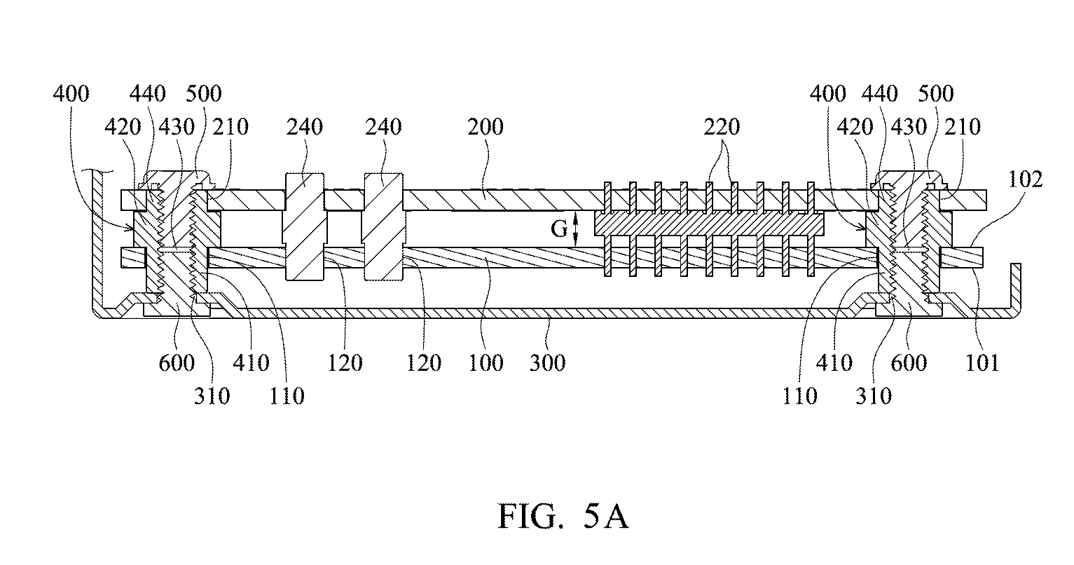

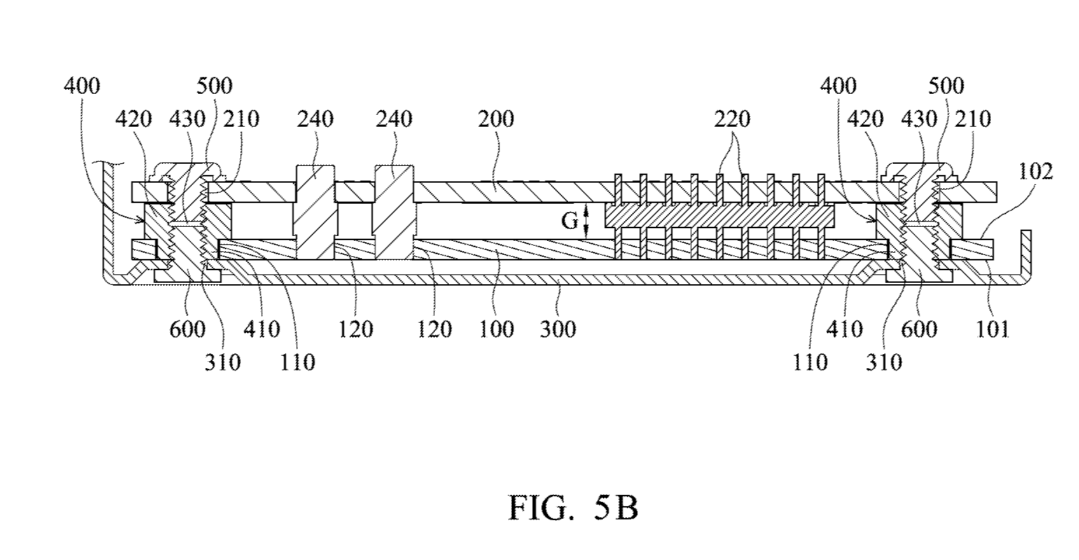

Referring to FIG. 5A, in another embodiment of the invention, the supporting member 400 can further comprise a third portion 440. The second portion 420 is disposed between the first portion 410 and the third portion 440, and the screw hole 430 further extends to the top of the third portion 440. When the second circuit board 200 is affixed to the supporting member 400 by the first locking member 500, the third portion 440 is disposed in the second hole 210. It should be noted that the dimensions or the diameter of the third portion 440 is less than that of the second portion 420, and the diameter and the shape of the third portion 440 are substantially the same as that of the second hole 210. In this embodiment, the dimensions or the diameter of the first portion 410 is substantially the same as that of the third portion 440.

As shown in FIG. 5B, in another embodiment, the height of the first portion 410 of the supporting member 400 is less than or the same as the height of the first hole 110, such that the first portion 410 does not protrude from the first surface 101 of the first circuit board 100. When the first circuit board 100 is affixed to the housing 300 by the second locking member 600, the first circuit board 100 might contact the housing. Thus, in this embodiment, the housing 300 can be made of a non-conductive material (such as plastic). In some embodiments, the first circuit board 100 can be disposed on an external platform directly, and the housing 300 and the second locking member 600 can be omitted.

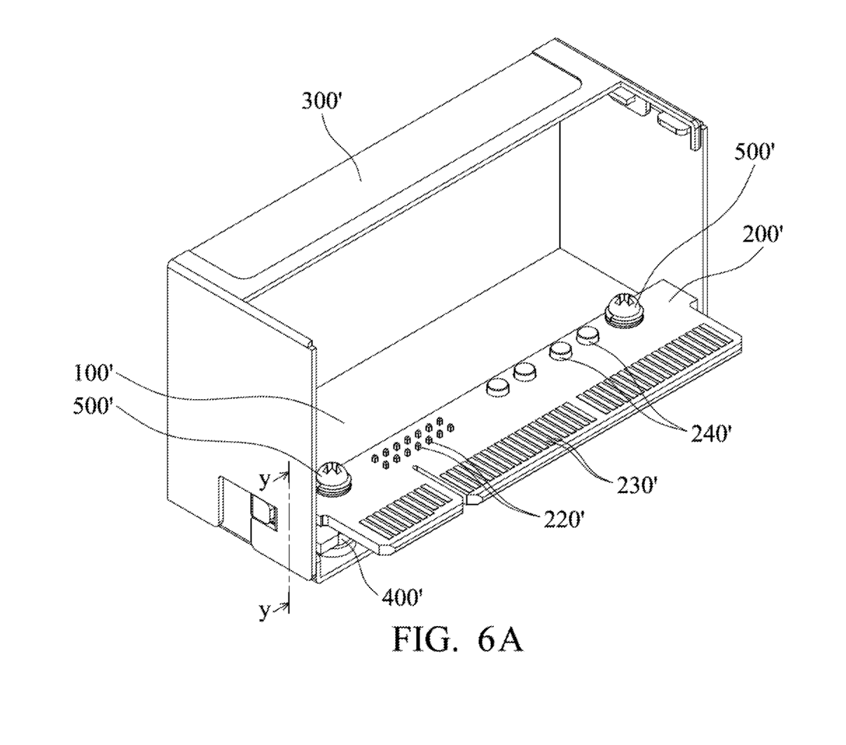

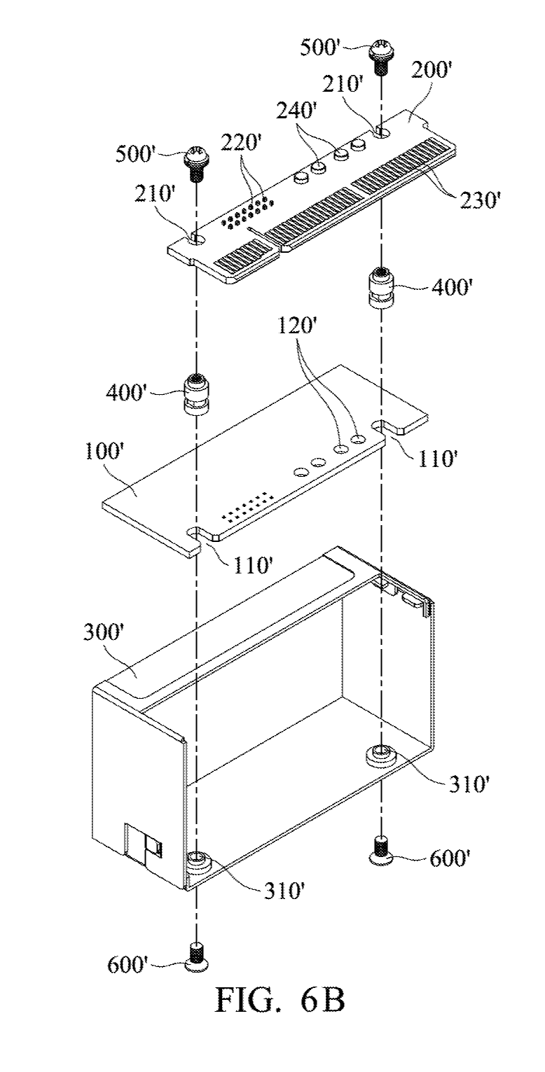

Referring to FIGS. 6A and 6B, an electronic device in another embodiment of the invention primarily comprises a first circuit board 100′, a second circuit board 200′, a housing 300′, at least one supporting member 400′, at least one first locking member 500′, and at least one second locking member 600′. At least one first hole 110′ and a plurality of perforations 120′ are formed on the first circuit board 100′. At least one second hole 210′, at least one pin 220′, at least one metal connector 230′, and a plurality of copper pillars 240′ are formed on the second circuit board 200′. Furthermore, at least one third hole 310′ is formed on the housing 300′.

The first hole 110′, the second hole 210′, and the third hole 310′ are aligned with each other, and the copper pillars 240′ are aligned with the perforations 120′. In other words, the relative position between the first hole 110′ and the perforations 120′ is the same as the relative position between the second hole 210′ and the copper pillars 240′.

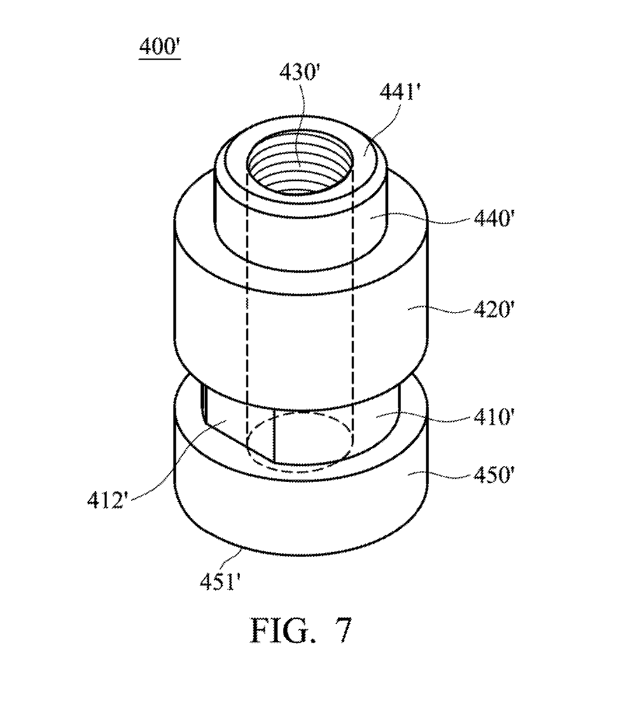

Referring to FIG. 7, in this embodiment, the supporting member 400′ comprises a first portion 410′, a second portion 420′, a screw hole 430′, a third portion 440′, and a fourth portion 450′, wherein the first portion 410′ is disposed between the second portion 420′ and the fourth portion 450′, and the second portion 420′ is disposed between the first portion 410′ and the third portion 440′. The width of the first portion 410′ is less than the diameter of the second portion 420′, the diameter of the third portion 440′ is less than that of the second portion 420′, and the diameter of the fourth portion 450′ exceeds the width of the first portion 410′. The screw hole 430′ extends from the bottom 451′ of the fourth portion 450′ to the top 441′ of the third portion 440′.

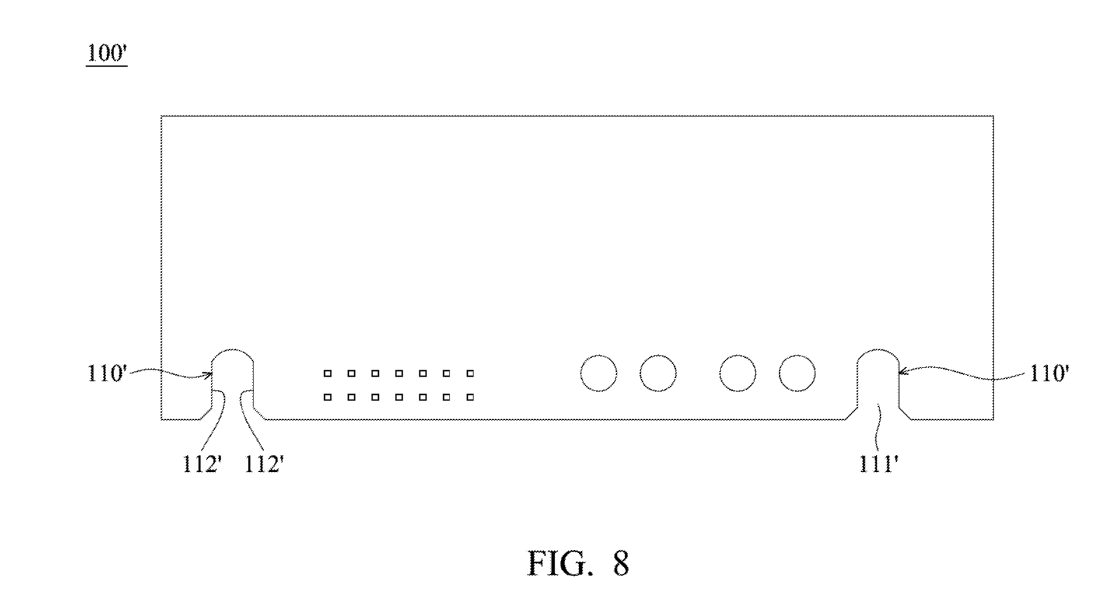

Referring to FIGS. 7 and 8, the first hole 110′ on the first circuit board 100′ has an opening 111′ provided open at the periphery of the first circuit board 100′, and the inner wall of the first hole 110′ forms a plane portion 112′. The height of the first portion 410′ of the supporting member 400′ is substantially the same as that of the first hole 110′, and the dimensions, the width, and the shape of the first portion 410′ are also substantially the same as that of the first hole 110′. That is, a plane region 412′ corresponding to the plane portion 112′ is formed on the first portion 410′. Therefore, the first portion 410′ can be exactly accommodated in the first hole 110′ through the opening 111′ to dispose the supporting member 400′ on the first circuit board 100′.

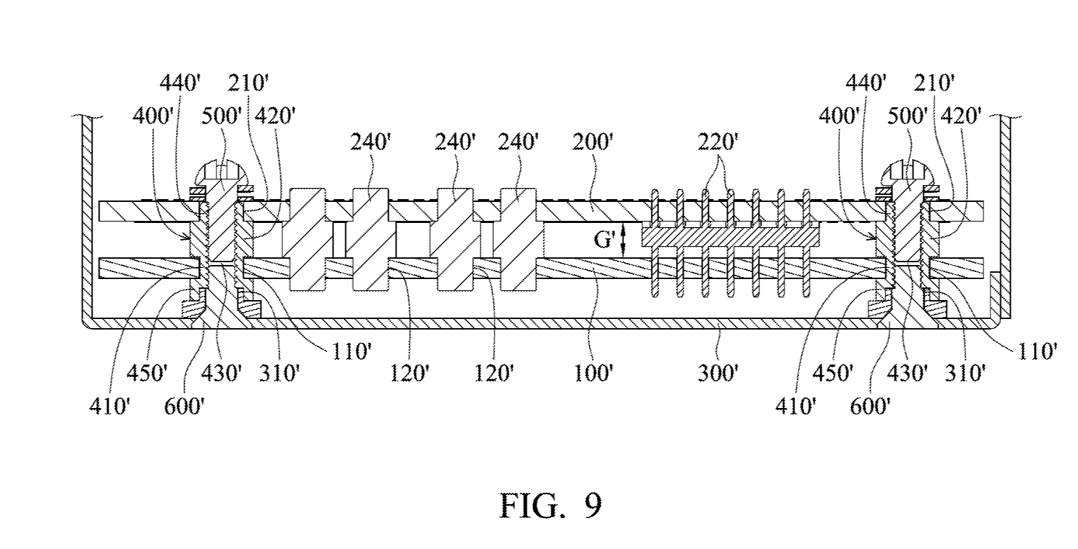

As shown in FIG. 9, when the supporting member 400′ is disposed on the first circuit board 100′, the second circuit board 200′ can be disposed on the supporting member 400′, and the third portion 440′ can be disposed in the second hole 210′. The first locking member 500′ can pass through the second hole 210′ and enter the screw hole 430′ to join to the supporting member 400′, such that the second circuit board 200′ can be affixed to the supporting member 400′. The pins 220′ of the second circuit board 200′ connect to the first circuit board 100′, and the copper pillars 240′ pass through the perforations to connect the first circuit board 100′. The first and second circuit boards 100′ and 200′ can transmit signals and power therebetween by the pins 220′ and the copper pillars 240′.

Subsequently, the pins 220′ and the copper pillars 240′ can be affixed to the first circuit board 100′ by welding. For example, the pins 220′ and the copper pillars 240′ can be affixed to the first circuit board by a surface-mount technology (SMT). Since the pins 220′ and the copper pillars 240′ are affixed to the first circuit board 100′, and the second circuit board 200′ is affixed to the supporting member 400′ by the first locking member 500′, the supporting member 400′ will not separate from the first circuit board 100′ through the opening 111′. Furthermore, because the first hole 110′ has the plane portion 112′, the supporting member 400′ will not rotate relative to the first circuit board 100′.

The second portion 420′ of the supporting member 400′ is disposed between the first circuit board 100′ and the second circuit board 200′, such that a gap G′ is formed between the first circuit board 100′ and the second circuit board 200′. The position of the second circuit board can be raised.

As shown in FIG. 9, the second locking member 600′ passes through the third hole 310′ on the housing 300′ and enters the screw hole 430′ from the fourth portion 450′ to join to the supporting member 400′, such that the first circuit board 100′ can be affixed to the housing 300′. Similarly, the fourth portion 450′ can separate the first circuit board 100′ from the housing 300′. Thus, the first circuit board 100′ does not contact the housing 300′ to generate a short circuit even if the housing 300′ comprises a conductive material (such as a metal).

In this embodiment, the width of the first portion 410′ is substantially the same as the diameter of the third portion 440′ and the diameter of the second hole 210′, and the diameter of the second portion 420′ is substantially the same as that of the fourth portion 450′. In some embodiments, the third portion 440′, the fourth portion 450′, the housing 300′, or the second locking member 600′ can be omitted as required.

In this embodiment, the supporting member 400′ can be affixed without welding or pressing, the cost of the processing and the material can be reduced. Furthermore, when the user wants to replace the supporting member 400′, the supporting member 400′ can be easily detached.

In summary, an electronic device having a supporting member is provided. By the aforementioned supporting member, a gap can be formed between a first circuit board and a second circuit board, and the first circuit board and the second circuit board can be affixed together at the position of the supporting member. Therefore, the space for configuring the lines or dissipating heat can be released, and the cost of the material can be reduced. Furthermore, the processing for aligning the holes and height can be simplified.

Although some embodiments of the present disclosure and their advantages have been described in detail, it should be understood that various changes, substitutions and alterations can be made herein without departing from the spirit and scope of the disclosure as defined by the appended claims. For example, it will be readily understood by those skilled in the art that many of the features, functions, processes, and materials described herein may be varied while remaining within the scope of the present disclosure. Moreover, the scope of the present application is not intended to be limited to the particular embodiments of the process, machine, manufacture, compositions of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps. Moreover, the scope of the appended claims should be accorded the broadest interpretation so as to encompass all such modifications and similar arrangements.

While the invention has been described by way of example and in terms of preferred embodiment, it is to be understood that the invention is not limited thereto. On the contrary, it is intended to cover various modifications and similar arrangements (as would be apparent to those skilled in the art). Therefore, the scope of the appended claims should be accorded the broadest interpretation to encompass all such modifications and similar arrangements.

What is claimed is:

1. An electronic device, comprising:
a first circuit board, having at least one first hole:
at least one supporting member, comprising a first portion, a second portion, and a screw hole extending from the first portion to the second portion, wherein the first portion is disposed in the first hole, and the diameter of the first portion is less than that of the second portion;
a second circuit board, having at least one second hole; and
a first locking member, passing through the second hole and entering the screw hole to affix the second circuit board to the supporting member, wherein the second portion is disposed between the first circuit board and the second circuit board to form a gap therebetween.

2. The electronic device as claimed in claim 1, wherein the diameter of the first portion is substantially the same as that of the first hole.

3. The electronic device as claimed in claim 1, wherein the second portion contacts the first circuit board.

4. The electronic device as claimed in claim 1, wherein the supporting member further comprises a third portion disposed in the second hole, wherein the diameter of the third portion is less than that of the second portion, and the screw hole further extends to the third portion.

5. The electronic device as claimed in claim 4, wherein the diameter of the third portion is substantially the same as that of the second hole.

6. The electronic device as claimed in claim 1, wherein the electronic device further comprises a housing having a third hole and a second locking member, wherein the second locking member passes through the third hole and enters the screw hole to affix the first circuit board to the housing.

7. The electronic device as claimed in claim 6, wherein the first locking member and the second locking member are disposed on opposite sides of the first circuit board.

8. The electronic device as claimed in claim 6, wherein the first circuit board further comprises a first surface and a second surface opposite to the first surface, wherein the second portion is disposed on the second surface, and the first portion protrudes from the first surface.

9. The electronic device as claimed in claim 1, wherein the supporting member is affixed to the first circuit board by welding or pressing.

10. The electronic device as claimed in claim 1, wherein the first circuit board is substantially parallel to the second circuit board.

11. An electronic device, comprising:
a first circuit board, having at least one first hole, wherein an inner wall of the first hole has at least one plane portion:
at least one supporting member, comprising a first portion, a second portion, and a screw hole extending from the first portion to the second portion, wherein the first portion is disposed in the first hole, the diameter of the first portion is less than that of the second portion, and the width and the shape of the first portion are substantially the same as that of the first hole;
a second circuit board, having at least one second hole; and
a first locking member, passing through the second hole and entering the screw hole to affix the second circuit board to the supporting member, wherein the second portion is disposed between the first circuit board and the second circuit board to form a gap therebetween.

12. The electronic device as claimed in claim 11, wherein the first hole comprises an opening.

13. The electronic device as claimed in claim 11, wherein the second portion contacts the first circuit board.

14. The electronic device as claimed in claim 11, wherein the supporting member comprises a third portion disposed in the second hole, wherein the diameter of the third portion is less than that of the second portion, and the screw hole further extends to the third portion.

15. The electronic device as claimed in claim 14, wherein the diameter of the third portion is substantially the same as that of the second hole.

16. The electronic device as claimed in claim 11, wherein the supporting member further comprises a fourth portion connected to the first portion, and the first portion is disposed between the second portion and the fourth portion, wherein the width of the first portion is less than the diameter of the fourth portion.

17. The electronic device as claimed in claim 16, wherein the height of the first portion is substantially the same as that of the first hole.

18. The electronic device as claimed in claim 11, wherein the electronic device further comprises a housing having a third hole and a second locking member, wherein the second locking member passes through the third hole and enters the screw hole to affix the first circuit board to the housing.

19. The electronic device as claimed in claim 11, wherein the first locking member and the second locking member are disposed on opposite sides of the first circuit board.

20. The electronic device as claimed in claim 11, wherein the first circuit board is substantially parallel to the second circuit board.
